(19) United States
(12) Patent Application Publication
(10) Pub. No.: US 2013/0077257 A1
(43) Pub. Date: Mar. 28, 2013

(54) ELECTRONIC DEVICE AND IMAGE SENSOR HEAT DISSIPATION STRUCTURE

(71) Applicant: Yi-Yuan Tsai, Changhua County (TW)

(72) Inventor: Yi-Yuan Tsai, Changhua County (TW)

(73) Assignee: ALTEK CORPORATION, Hsinchu City (TW)

(21) Appl. No.: 13/282,480

(22) Filed: Oct. 27, 2011

(30) Foreign Application Priority Data
Sep. 22, 2011 (TW) 100134179

(51) Int. Cl. H05K 7/20

(52) U.S. Cl. 361/720

(57) ABSTRACT

An electronic device including a main board, an image sensor heat dissipation structure and a lens module is provided. The image sensor heat dissipation structure includes a heat dissipation plate, a thermal interface layer, an image sensor package and a cover glass. The heat dissipation plate is fixed to the main board. The thermal interface layer is disposed on the heat dissipation plate. The image sensor package including a circuit board, a plurality of pads, an image sensor and an encapsulant is fixed to the thermal interface layer. The circuit board has an opening. The image sensor is electrically connected to the circuit board through the pads, wherein the light receiving surface faces the opening and the back surface faces the thermal interface layer.

### CROSS-REFERENCE TO RELATED APPLICATION

This application claims the priority benefit of Taiwan application serial no. 100134179, filed on Sep. 22, 2011. The entirety of the above-mentioned patent application is hereby incorporated by reference herein and made a part of this specification.

### BACKGROUND OF THE INVENTION

1. Technical Field

The present invention relates to an electronic device. More particularly, the present invention relates to an electronic device having an image sensor heat dissipation structure.

2. Description of Related Art

Computers, handsets, digital cameras and liquid crystal displays (LCD) are indispensable in the modern people life, but none of them is a product not related to the semiconductor industry. In terms of the peripheral products related to the semiconductor industry, the products are more numerous and various, which demonstrates the solid potential and signification importance of the electronic industry. In recent years, along with the rapid increasing demands of customers on the electronic product function, the multifunction, the portability and the light-handiness, the package process manufacturers have switched the process direction from the conventional technology into the high precision process featuring high power, high density, lightness, thinness and miniaturization. In addition to the above-mentioned tendency, an electronic package also needs to keep the basic characteristics, such as high reliability, good heat dissipation and low manufacturing cost, so to confront the challenge of the time urgency for launching a new product and the shorter and shorter life-period of a product.

Among numerous electronic products, the video multimedia product is the most popular one, while after launching digital cameras, digital camcorders and image scanners, the image digitization has become the necessary trend. The key component and sub-assembly for the above-mentioned video multimedia products is the image sensor. In fact, the image sensor is a semiconductor chip, which is able to convert an optical signal into an electronic signal and includes a photo-sensing component, for example, a complementary metal-oxide semiconductor (CMOS) or a charge-coupled device (CCD).

In general, the signal receiving pad of the image sensor is designed on the surface opposing the light receiving surface, i.e., the back surface of the image sensor package. And then, the image sensor package is fixed on the printed circuit board (PCB) or a flexible printed circuit board (FPCB) by a wire bonding method. However, in such configuration the back surface opposing the light receiving surface of the image sensor is covered by the printed circuit board or flexible printed circuit board, so that the image sensor cannot perform heat dissipation through a conduction or convection. Thus, in order to make the image sensor meet the development of the portable electronic device market, how to improve the heat dissipation of the image sensor with a simple structure is becoming one of the major issues in the future development.

### SUMMARY OF THE INVENTION

The present invention provides an electronic device capable of a good heat dissipation effect through an image sensor heat dissipation structure having a simple structure.

The present invention provides an image sensor heat dissipation structure adapted to use in an electronic device and capable of a good heat dissipation effect with a simple structure and further improves the efficiency of the electronic device.

The present invention provides an electronic device including a main board, an image sensor heat dissipation structure and a lens module. The image sensor heat dissipation structure is disposed on the main board including a heat dissipation plate, a thermal interface layer, an image sensor package and a glass cover. The heat dissipation plate is fixed on the main board. The thermal interface layer is disposed on the heat dissipation plate, wherein the heat dissipation plate is located between the main board and the thermal interface layer. The image sensor package is fixed to the thermal interface layer and includes a circuit board, a plurality of pads, an image sensor and an encapsulant. The circuit board has a first surface, a second surface opposing the first surface and an opening. The pads are disposed on the first surface and located around the opening. The image sensor has a light receiving surface and a back surface opposing the light receiving surface and electrically connected to the first surface of the circuit board through the pads. Herein the light receiving surface faces the opening and the back surface faces the thermal interface layer. The encapsulant is used to encapsulate the image sensor and the pads, and located between the first surface of the circuit and the thermal interface layer. The glass cover is disposed at the opening and covers the image sensor. The lens module covers the glass cover and disposed at the image sensor heat dissipation structure. The image sensor heat dissipation structure is located between the lens module and the main board.

The present invention further provides an image sensor heat dissipation structure disposed in an electronic device. The electronic device includes a main board and a lens module. The image sensor heat dissipation structure is disposed on the main board. The lens module is disposed at the image sensor heat dissipation structure, and the image sensor heat dissipation structure is located between the lens module and the main board. The image sensor heat dissipation structure includes a heat dissipation plate, a thermal interface layer, an image sensor package and a glass cover. The heat dissipation plate is fixed on the main board. The thermal interface layer is disposed on the heat dissipation plate, wherein the heat dissipation plate is located between the main board and the thermal interface layer. The image sensor package is fixed to the thermal interface layer and includes a circuit board, a plurality of pads, an image sensor and an encapsulant. The circuit board has a first surface, a second surface opposing the first surface and an opening. The pads are disposed on the first surface and located around the opening. The image sensor has a light receiving surface and a back surface opposing the light receiving surface and electrically connected to the first surface of the circuit board through the pads. Herein the light receiving surface faces the opening and the back surface faces the thermal interface layer. The encapsulant is used to encapsulate the image sensor and the pads, and located between the first surface of the circuit and the thermal interface layer. The glass cover is disposed at the opening and covers the image sensor.

According to one embodiment of the present invention, the thermal interface layer is a thermal conductive grease, a thermal conductive paste or a thermal conductive pad.

According to one embodiment of the present invention, the heat dissipation plate is a metal plate.

According to one embodiment of the present invention, the heat dissipation plate is a portion of a screen supporting structure of the electronic device.

According to one embodiment of the present invention, the heat dissipation plate comprises a fin set disposed on a surface of the heat dissipation plate and the fin set is located between the heat dissipation plate and the main board.

According to one embodiment of the present invention, the circuit board is a printed circuit board or a flexible printed circuit board.

In light of the above, in the electronic device of the present invention, the image sensor can perform heat dissipations through a conduction or convection, since the heat dissipation plate and the thermal interface layer are disposed on the back side of the image sensor. Thus, through the configuration of the image sensor heat dissipation structure, the heat dissipation problem of the electronic device of the present invention can be improved, so that the image sensor can be used with a higher operating frequency and the efficiency of the electronic device is further improved.

Several exemplary embodiments accompanied with figures are described in detail below to further describe the disclosure in detail.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic view of an electronic device according to an embodiment consistent with the invention.

FIG. 2 is a schematic view of an image sensor heat dissipation structure of the electronic device in FIG. 1.

FIG. 3 is a schematic cross-sectional view illustrating the image sensor heat dissipation structure shown in FIG. 2 along the line A-A.

### DESCRIPTION OF EMBODIMENTS

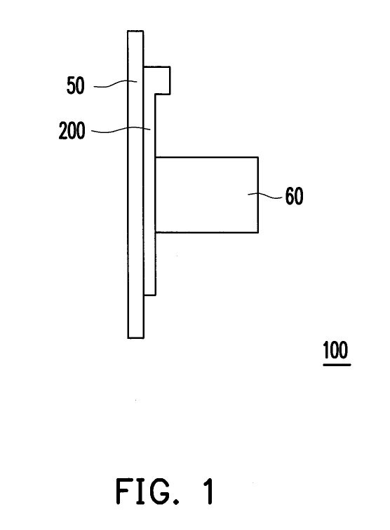

FIG. 1 is a schematic view of an electronic device according to an embodiment consistent with the invention. Referring to FIG. 1, the electronic device 100 of the embodiment is for example, a camera and includes a main board 50, an image sensor heat dissipation structure 200 and a lens module 60. The image sensor heat dissipation structure 200 is disposed on the main board 50. The lens module 60 is disposed at the image sensor heat dissipation structure 200, and the image sensor heat dissipation structure 200 is located between the lens module 60 and the main board 50.

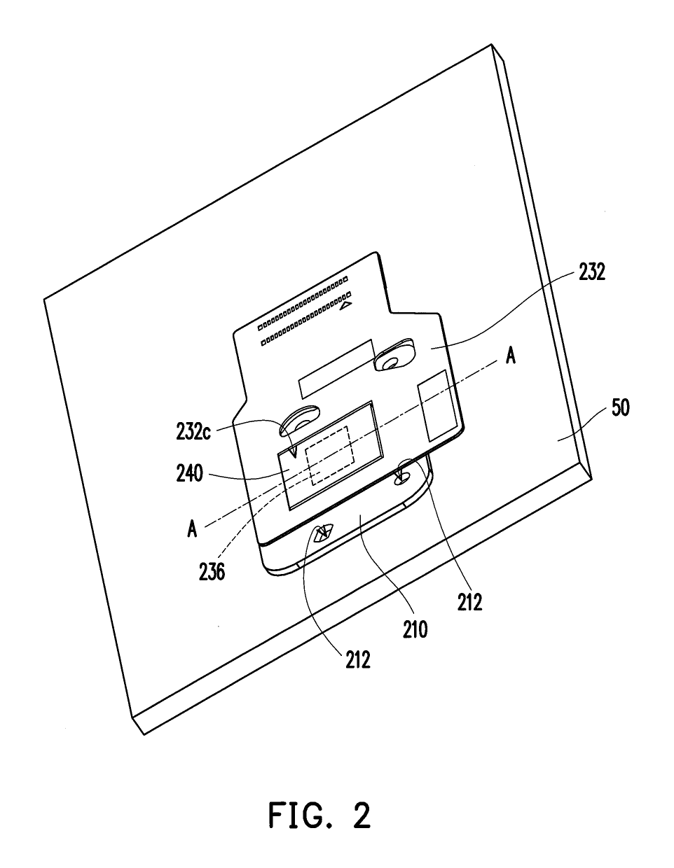

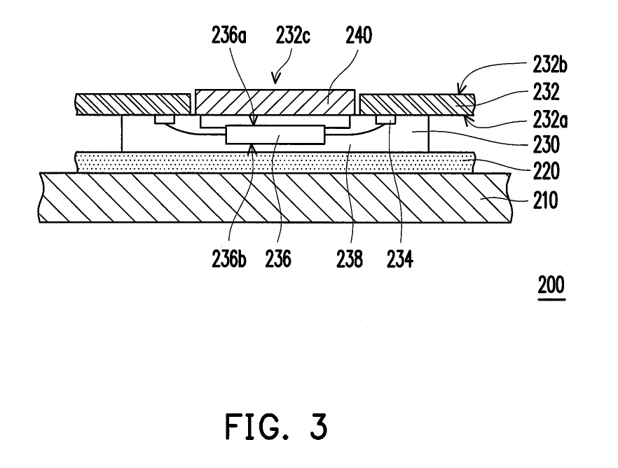

FIG. 2 is a schematic view of an image sensor heat dissipation structure of the electronic device in FIG. 1. FIG. 3 is a schematic cross-sectional view illustrating the image sensor heat dissipation structure shown in FIG. 2 along the line A-A. Referring to FIG. 2 and FIG. 3 together, the image sensor heat dissipation structure 200 includes a heat dissipation plate 210, a thermal interface layer 220, an image sensor package 230 and a glass cover 240.

In the embodiment, the image sensor heat package 230 is fixed to the thermal interface layer 220, and the thermal interface layer 220 is disposed on the heat dissipation plate 210. The thermal interface layer 220 is used to transfer heat by means of conduction, so that the heat generated by the image sensor package 230 can be dissipated to the heat dissipation plate 210, and the heat dissipation plate 210 further transfers the heat to the surrounding by means of convection. Thus, the heat dissipation plate 210 is preferred to be a metal plate. Moreover, to simplify the structure, the heat dissipation plate 210 can be the original metal sheet which is a portion of the electronic device 100 itself, for example, a metal sheet of the screen supporting structure (not shown) of the electronic device 100. Accordingly, the electronic device 100 of the embodiment can directly use a portion of the original internal component as the heat dissipation plate 210, no extra element is needed to dispose. And the thermal interface layer 220 can be disposed to the heat dissipation plate 210 so that the image sensor package 230 can obtain the thermal dissipation effect. Furthermore, the area of the metal sheet inside the electronic device 100 contacting with air is larger than that of the image sensor contacting with air, thus using the heat dissipation 210 can improve the thermal dissipation effect of the electronic device 100. In addition, the heat dissipation plate 210 can also include a fin set (not shown) disposed on a surface of the heat dissipation plate 210 which the thermal interface layer 220 is not disposed, so as to further improve the heat dissipation of the electronic device 100. Furthermore, the thermal interface layer 220 can be a thermal conductive grease, a thermal conductive paste, a thermal conductive pad or any other suitable thermal conductive material, and the present invention is not limited thereto.

Referring to FIG. 3, an image sensor package 230 of the present embodiment includes a circuit board 232, a plurality of pads 234, an image sensor 236 and an encapsulant 238. In the embodiment, the image sensor 236 may be a charge coupled device (CCD) image sensor or a complementary metal oxide semiconductor (CMOS) sensor. In order to let the image sensor 236 operate in a higher operation frequency, in order to improve the efficiency of the image sensor 236, or in order to prevent the image sensor 236 from being overheated, the heat generated by the image sensor 236 has to be dissipated rapidly in a great quantity. Thus, in the embodiment, the packaging of the image sensor 236 is different from the conventional package.

Specifically, as shown in FIG. 3, the circuit board 232 has a first surface 232a, a second surface 232b opposing the first surface 232a and an opening 232c. In the present embodiment, the circuit board 232 is a printed circuit board (PCB) or a flexible printed circuit board (FPCB), but the present invention is not limited thereto. The image sensor 236 has a light receiving surface 236a and a back surface 236b opposing the light receiving surface 236a. In the embodiment, the image sensor 236 is electrically connected to the first surface 232a of the circuit board 232 through the pads 234, wherein the light receiving surface 236a faces the opening 232c and the back surface 236b faces the thermal interface layer 220. The pads 234 are disposed on the first surface 232a of the circuit board 232 and located around the opening 232c.

In general, the conventional image sensor is packaged in the orientation of the back surface of the image sensor attaching the circuit board through the pads. However, in the embodiment as shown in FIG. 3, in order to let the back surface 236b of the image sensor 236 be attached to the thermal interface layer 220, the image sensor 236 is packaged in the orientation of the light receiving surface 236a facing or attaching the circuit board 232. Additionally, in order to receive the incident light, an opening 232c is disposed at the circuit board 232, and the image sensor 236 is disposed at the opening 232c. Therefore, the image sensor 236 can achieve a better heat dissipation effect.

Referring to FIG. 3, the image sensor 230 further includes an encapsulant 238. The encapsulant 238 is used to package the image sensor 236 and the pads 234. The encapsulant 238 of the embodiment is located between the first surface 232a of the circuit board 232 and the thermal interface layer 220. It should be noted that the material of the encapsulant 238 can be resin or ceramic, and the present invention is not limited thereto. But in order to improve the heat dissipation, the material of the encapsulant 238 of the embodiment is ceramic. Besides, to provide the image sensor 236 a good protection, a glass cover 240 is disposed on the second surface 232b of the circuit board 232. And the glass cover 240 is located at the opening 232c of the circuit board 232 and covers the image sensor 236.

Referring to FIG. 2, to dispose the lens module 60 to the image sensor heat dissipation structure 200, a plurality of holes 212 are disposed on the heat dissipation plate 210 of the embodiment, so that the lens module 60 can be screwed up to the heat dissipation plate 210. However, the fixing manner of the lens module 60 and the image sensor heat dissipation plate 200 is not limited in the present invention.

In light of the foregoing, in the electronic device of the present invention, the image sensor can perform heat dissipations through a conduction or convection, since the heat dissipation plate and the thermal interface layer are disposed on the back side of the image sensor. Thus, through the configuration of the image sensor heat dissipation structure, the heat dissipation problem of the electronic device of the present invention can be improved, so that the image sensor can be used with a higher operating frequency and the efficiency of the electronic device is further improved. In addition, since the metal sheet originally disposed inside the internal of the electronic device, e.g., the portion of metal sheet of the screen supporting structure, can be used as the heat dissipation plate, the electronic device can be simple in structure and achieve a better heat dissipation.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An electronic device, comprising:
a main board;
an image sensor heat dissipation structure disposed on the main board, comprising:
a heat dissipation plate fixed on the main board;
a thermal interface layer disposed on the heat dissipation plate, wherein the heat dissipation plate is located between the main board and the thermal interface layer;
an image sensor package fixed to the thermal interface layer, comprising:
a circuit board having a first surface, a second surface opposing the first surface and an opening;
a plurality of pads disposed on the first surface and located around the opening;
an image sensor having a light receiving surface and a back surface opposing the light receiving surface, and electrically connected to the first surface of the circuit board through the pads, wherein the light receiving surface faces the opening and the back surface faces the thermal interface layer;
an encapsulant used to encapsulate the image sensor and the pads and located between the first surface of the circuit and the thermal interface layer; and
a glass cover disposed at the opening and covering the image sensor; and
a lens module covering the glass cover and disposed at the image sensor heat dissipation structure, wherein the image sensor heat dissipation structure is located between the lens module and the main board.

2. The electronic device as claimed in claim 1, wherein the thermal interface layer is a thermal conductive grease, a thermal conductive paste or a thermal conductive pad.

3. The electronic device as claimed in claim 1, wherein the heat dissipation plate is a metal plate.

4. The electronic device as claimed in claim 3, wherein the heat dissipation plate is a portion of a screen supporting structure of the electronic device.

5. The electronic device as claimed in claim 3, wherein the heat dissipation plate comprises a fin set disposed on a surface of the heat dissipation plate and the fin set is located between the heat dissipation plate and the main board.

6. The electronic device as claimed in claim 1, wherein the circuit board is a printed circuit board or a flexible printed circuit board.

7. An image sensor heat dissipation structure adapted to dispose in an electronic device, the electronic device comprising a main board and a lens module, the image sensor heat dissipation structure disposed on the main board and located between the lens module and the main board, the image sensor heat dissipation structure comprising:
a heat dissipation plate fixed on the main board;
a thermal interface layer disposed on the heat dissipation plate, wherein the heat dissipation plate is located between the main board and the thermal interface layer;
an image sensor package fixed to the thermal interface layer, comprising:
a circuit board having a first surface, a second surface opposing the first surface and an opening;
a plurality of pads disposed on the first surface and located around the opening;
an image sensor having a light receiving surface and a back surface opposing the light receiving surface, and electrically connected to the first surface of the circuit board through the pads, wherein the light receiving surface faces the opening and the back surface faces the thermal interface layer; and
an encapsulant used to encapsulate the image sensor and the pads and located between the first surface of the circuit and the thermal interface layer; and
a glass cover disposed at the opening and covering the image sensor.

8. The image sensor heat dissipation structure as claimed in claim 7, wherein the thermal interface layer is a thermal conductive grease, a thermal conductive paste or a thermal conductive pad.

9. The image sensor heat dissipation structure as claimed in claim 7, wherein the heat dissipation plate is a metal plate.

10. The image sensor heat dissipation structure as claimed in claim 9, wherein the heat dissipation plate is a portion of a screen supporting structure of the electronic device.

11. The image sensor heat dissipation structure as claimed in claim 9, wherein the heat dissipation plate comprises a fin set disposed on a surface of the heat dissipation plate and the fin set is located between the heat dissipation plate and the main board.

12. The image sensor heat dissipation structure as claimed in claim 7, wherein the circuit board is a printed circuit board or a flexible printed circuit board.
